(19) United States
(12) Patent Application Publication
(10) Pub. No.: US 2021/0285095 A1
(43) Pub. Date: Sep. 16, 2021

(54) Limitation Device, Limitation Structure, Adjustment Method Thereof and Evaporation System

(71) Applicants: HEFEI XINSHENG OPTOELECTRONICS TECHNOLOGY CO., LTD., Hefei, Anhui (CN); BOE TECHNOLOGY GROUP CO., LTD., Beijing (CN)

(72) Inventors: Tingyuan DUAN, Beijing (CN); Qinghua ZOU, Beijing (CN); Gu YAO, Beijing (CN)

(21) Appl. No.: 16/332,643

(22) PCT Filed: May 24, 2018
(86) PCT No.: PCT/CN2018/088180

§ 371 Date: Mar. 12, 2019

(30) Foreign Application Priority Data
Aug. 29, 2017 (CN) 201710758151.7

(51) Int. Cl. C23C 14/54; C23C 14/24

(52) U.S. Cl. CPC C23C 14/542; C23C 14/24

(57) ABSTRACT

The present application provides a limitation device for evaporation, a limitation structure, an adjustment method thereof, and an evaporation system. The limitation device for evaporation includes a limitation structure. The limitation structure includes a first adjustment structure and a second adjustment structure disposed on a same plane. A side of the first adjustment structure faces a side of the second adjustment structure, and the first adjustment structure and the second adjustment structure are spaced apart from each other to form a spacing region. The first adjustment structure and the second adjustment structure are configured to be movable relative to each other to adjust a range of the spacing region.

### CROSS-REFERENCE TO RELATED APPLICATION

This application claims priority to Chinese Patent Application No. 201710758151.7, filed on Aug. 29, 2017, the entire contents of which are hereby incorporated by reference.

### TECHNICAL FIELD

The present disclosure relates to the field of evaporation technology, and in particular, to a limitation device for evaporation, a limitation structure, an adjustment method thereof, and an evaporation system.

### BACKGROUND

At present, the preparation of an organic electroluminescent device OLED is generally carried out by an evaporation method. For example, an organic light-emitting functional layer and a cathode in the organic electroluminescence device are usually formed by an evaporation method.

In a conventional point evaporation apparatus, limitation plates are usually employed to limit the evaporation range of the material in the evaporation source. In the region corresponding to the evaporation range limited by the limitation plates, a plurality of evaporation sources are usually provided. Each evaporation source has an identical evaporation range limited by the limitation plates.

### SUMMARY

In an aspect, the present disclosure provides a limitation device for evaporation, including a limitation structure. The limitation structure includes a first adjustment structure and a second adjustment structure disposed on a same plane, a side of the first adjustment structure is opposite to a side of the second adjustment structure, and the first adjustment structure and the second adjustment structure are spaced apart from each other to form a spacing region. The first adjustment structure and the second adjustment structure are movable relative to each other to adjust a range of the spacing region.

In some embodiments, the first adjustment structure and the second adjustment structure are arranged in a first direction perpendicular to a second direction; the first adjustment structure includes a plurality of first adjustment plates sequentially arranged in the second direction, and the second adjustment structure includes a plurality of second adjustment plates sequentially arranged in the second direction; the plurality of first adjustment plates correspond to the plurality of second adjustment plates in the first direction; and each of the plurality of first adjustment plates and each of the plurality of second adjustment plates are both movable in the first direction to adjust a spacing in the first direction between each of the plurality of first adjustment plates and a corresponding one of the plurality of second adjustment plates.

In some embodiments, the plurality of first adjustment plates and the plurality of second adjustment plates are in one-to-one correspondence in the first direction.

In some embodiments, a number of the plurality of first adjustment plates is the same as a number of the plurality of second adjustment plates, and a central axis of each of the plurality of first adjustment plates in the first direction and a central axis of the corresponding one of the plurality of second adjustment plates in the first direction mutually coincide.

In some embodiments, a dimension of each of the plurality of first adjustment plates in the second direction is 1/10 to 1/20 of a dimension of the first adjustment structure in the second direction; and a dimension of each of the plurality of second adjustment plates in the second directions is 1/10 to 1/20 of a dimension of the second adjustment structure in the second direction.

In some embodiments, adjacent ones of the plurality of first adjustment plates are substantially seamlessly connected; and adjacent ones of the plurality of second adjustment plates are substantially seamlessly connected.

In some embodiments, adjacent ones of the plurality of first adjustment plates overlap with each other at their connected edge regions; and adjacent ones of the plurality of second adjustment plates overlap with each other at their connected edge regions.

In some embodiments, mutually connected side edges of the adjacent ones of the first adjustment plates are fitted; and mutually connected side edges of the adjacent ones of the second adjustment plates are fitted.

In some embodiments, the limitation device further includes a first control part and a second control part; the first control part is coupled to a first adjustment plate of the limitation structure and configured to control movement of the first adjustment plate; and the second control part is coupled to a second adjustment plate of the limitation structure and configured to control movement of the second adjustment plate.

In some embodiments, the limitation device further includes a calculating part coupled to the first control part and the second control part and configured to calculate a spacing in the first direction between the first adjustment plate and the second adjustment plate corresponding to each other; and the first control part and the second control part are configured to control the first adjustment plate and the second adjustment plate to move in the first direction based on the calculated spacing, respectively.

In some embodiments, the spacing region is configured to allow an evaporation material evaporated from an evaporation source at a side of the limitation device to pass through the spacing region to be deposited on a substrate at an opposite side of the limitation device, and wherein the limitation device is configured to adjust an evaporation range of the evaporation source by adjusting the spacing region.

In another aspect, the present disclosure provides an evaporation system, including the limitation device described herein.

In yet another aspect, the present disclosure provides an adjustment method of the limitation structure described herein. The method includes a step of: moving a first adjustment structure and a second adjustment structure relative to each other, thereby adjusting a range of a spacing region formed between the first adjustment structure and the second adjustment structure.

In some embodiments, the first adjustment structure and the second adjustment structure are arranged in a first direction perpendicular to a second direction; the first adjustment structure includes a plurality of first adjustment plates sequentially arranged in the second direction, and the second adjustment structure include a plurality of second adjustment plates sequentially arranged in the second direction; the plurality of first adjustment plates correspond to the plurality of second adjustment plates in the first direction; a substrate to be coated is configured to be moved in the first direction to achieve evaporation of a material on the substrate to be coated, and wherein the step of moving the first adjustment structure and the second adjustment structure relative to each other includes: moving each of the plurality of first adjustment plates of the first adjustment structure and a corresponding one of the plurality of second adjustment plates of the second adjustment structure in the first direction, thereby adjusting a spacing in the first direction between each of the plurality of first adjustment plates and the corresponding one of the plurality of second adjustment plates.

In still another aspect, the present disclosure provides an adjustment method of the limitation device described herein. The method includes the adjustment method of the limitation structure described above.

In some embodiments, the first adjustment structure and the second adjustment structure are arranged in a first direction perpendicular to a second direction; the first adjustment structure includes a plurality of first adjustment plates sequentially arranged in the second direction, and the second adjustment structure includes a plurality of second adjustment plates sequentially arranged in the second direction; and the plurality of first adjustment plates correspond to the plurality of second adjustment plates in the first direction; the limitation device further includes a first control part coupled to a first adjustment plate of the limitation structure and a second control part coupled to a second adjustment plate of the limitation structure; and wherein the method further includes: moving, by the first control part and the second control part respectively, the first adjustment plate of the first adjustment structure and the second adjustment plate of the second adjustment structure in the first direction to adjust a spacing in the first direction between the first adjustment plate and the second adjustment plate corresponding to each other.

In some embodiments, the limitation device further includes a calculating part coupled to the first control part and the second control part, and the adjustment method further includes: calculating, by the calculating part, the spacing in the first direction between the first adjustment plate and the second adjustment plate corresponding to each other; and controlling, by the first control part and the second control part respectively, the first adjustment plate and the second adjustment plate corresponding to each other to move in the first direction based on the calculated spacing.

### BRIEF DESCRIPTION OF THE DRAWINGS

FIG. 1 is a schematic view showing evaporation by a point evaporation apparatus in the related art;

FIG. 2 is a plan view showing a structure of a limitation plate of FIG. 1;

FIG. 3 is a plan view of a structure of a limitation structure in accordance with some embodiments of the present disclosure;

FIG. 4 is a plan view of a structure of a limitation device in accordance with some embodiments of the present disclosure;

FIG. 5 is a graph of a function Y(y) fitted by a calculating part in accordance with some embodiments of the present disclosure; and

FIG. 6 is a plan view of a structure of a limitation device adjusted in accordance with a curve of the function Y(y) in FIG. 5, in accordance with some embodiments of the present disclosure.

### DETAILED DESCRIPTION

The present disclosure will now be described more specifically with reference to the following embodiments. It is noted that the following description of some embodiments is presented herein for purposes of illustration and description. It is not intended to be exhaustive or to be limited to the precise form disclosed.

At present, the preparation of an organic electroluminescent device OLED is generally carried out by an evaporation method. For example, an organic light-emitting functional layer and a cathode in the organic electroluminescence device are usually formed by an evaporation method.

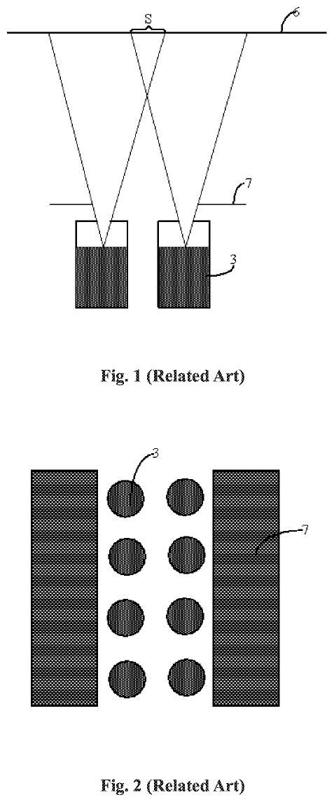

FIG. 1 is a schematic view showing evaporation by a point evaporation apparatus in the related art. FIG. 2 is a plan view showing a structure of limitation plates in FIG. 1. As shown in FIGS. 1 and 2, the point evaporation apparatus includes a plurality of evaporation sources 3, limitation plates 7, and a heating wire (not shown) closely adjacent to the evaporation sources 3. During evaporation, the heating wire is heated by a current to heat the evaporation sources 3 to evaporate the evaporation material in the evaporation sources 3. The evaporation material is evaporated at a certain angle onto a glass substrate 6 disposed above the evaporation apparatus to form a film. As shown in FIG. 1, the limitation plates 7 is disposed between the evaporation sources 3 and the glass substrate 6, and are configured to limit the evaporation range of the material in the evaporation sources 3. As shown in FIG. 2, the conventional limitation plates 7 are two plates spaced apart from each other that limit the evaporation range of the evaporation sources 3. The plurality of evaporation sources 3 are disposed within the evaporation range limited by the limitation plates 7. The evaporation range limited by the limitation plates 7 in FIG. 2 is identical for each evaporation source 3.

In the point evaporation apparatus, a film layer formed by a single evaporation source 3 has a thickness which is sequentially thinned from a part right above the evaporation source 3 to periphery, and during the evaporation process, there will be an evaporation overlapping region S between the evaporation sources 3, as shown in FIG. 1. The thickness of the film layer in the evaporation overlapping region S is a sum of the thicknesses of the film layers respectively formed by evaporation of, for example, two evaporation sources 3. Therefore, in a case where the evaporation time for each position of the glass substrate 6 is the same, the use of the above-described limitation plates 7 inevitably results in an uneven thickness of the film layer evaporated onto the entire glass substrate 6, and the performance of the product is deteriorated.

Accordingly, the present disclosure provides, inter cilia, a limitation device for evaporation, a limitation structure, an adjustment method thereof; and an evaporation system that substantially obviate one or more of the problems due to the limitations and disadvantages of the related art. In one aspect, the present disclosure provides a limitation structure. In some embodiments, the limitation structure includes a first adjustment structure and a second adjustment structure disposed on a same plane, a side of the first adjustment structure faces a side of the second adjustment structure, and the first adjustment structure and the second adjustment structure are spaced apart from each other to form a spacing region. In some embodiments, the first adjustment structure and the second adjustment structure are configured to be movable relative to each other to adjust a range of the spacing region.

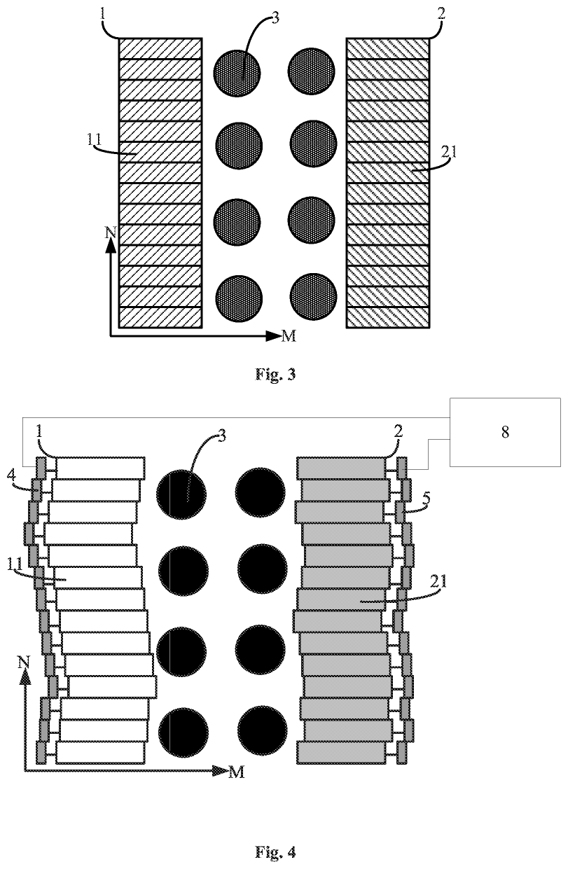

FIG. 3 is a plan view of a structure of a limitation structure in accordance with some embodiments of the present disclosure. As shown in FIG. 3, the limitation structure in some embodiments includes: a first adjustment structure 1 and a second adjustment structure 2 disposed on a same plane, a side of the first adjustment structure 1 faces a side of the second adjustment structure 2, and the first adjustment structure 1 and the second adjustment structure 2 are spaced apart from each other to form a spacing region. The first adjustment structure 1 and the second adjustment structure 2 are configured to be movable relative to each other to adjust a range of the spacing region.

In the limitation structure, as shown in FIG. 3 and referring to FIG. 1, a plurality of evaporation sources 3 are disposed below the spacing region, and the limitation structure is configured to limit an evaporation range of the evaporation sources 3. By providing the first adjustment structure 1 and the second adjustment structure 2 configured to be movable relative to each other, it is possible to adjust the range of the spacing region formed between the first adjustment structure 1 and the second adjustment structure 2, thereby the evaporation range of the evaporation sources 3 can be adjusted. Compared with the existing limitation plate structure by which the evaporation range limited cannot be adjusted, the limitation structure in the present embodiment can adjust the evaporation range, so that the thickness of the film layer formed by evaporation is more uniform, thereby improving the performance of the product formed by the evaporation and enhancing the competitiveness of the product.

As shown in FIG. 3, in some embodiments, the first adjustment structure 1 and the second adjustment structure 2 are arranged in a first direction M perpendicular to a second direction N; the first adjustment structure 1 includes a plurality of first adjustment plates 11, and the second adjustment structure includes a plurality of second adjustment plates 21. In some embodiments, the plurality of first adjustment plates 11 are sequentially arranged in the second direction N, and the plurality of second adjustment plates 21 are sequentially arranged in the second direction N. In some embodiments, the plurality of first adjustment plates 11 correspond to the plurality of second adjustment plates 21 in the first direction M. In some embodiments, each of the plurality of first adjustment plates 11 and each of the plurality of second adjustment plates 21 are both configured to be movable in the first direction M to adjust a spacing in the first direction M between each of the plurality of first adjustment plates 11 and a corresponding one of the plurality of second adjustment plates 21. In this way, the spacing in the first direction M between each of the plurality of first adjustment plates 11 of the first adjustment structure 1 and the corresponding one of the plurality of second adjustment plates 21 of the second adjustment structure 2 can be independently adjusted, so that the spacing in the first direction M between the first adjustment structure 1 and the second adjustment structure 2 can be arbitrarily adjusted at different positions in the second direction N, thereby allowing the evaporation range of the evaporation sources 3, which is limited between the first adjustment structure 1 and the second adjustment structure 2, can be arbitrarily adjusted, resulting in more uniform thickness of the film layer formed by evaporation.

In some embodiments, the plurality of first adjustment plates 11 and the plurality of second adjustment plates 21 are in one-to-one correspondence in the first direction M. For example, a first one of the plurality of first adjustment plates 11 in the second direction N corresponds to a first one of the plurality of second adjustment plates 21 in the second direction N, and a second one of the plurality of first adjustment plates 11 in the second direction N corresponds to a second one of the plurality of second adjustment plates 21 in the second direction N, and so forth. Optionally, the number of the plurality of first adjustment plates is the same as the number of the plurality of second adjustment plates. Optionally, a central axis of each of the plurality of first adjustment plates 11 in the first direction M and a central axis of the corresponding one of the plurality of second adjustment plates 21 in the first direction M mutually coincide.

In some embodiments, a dimension of each of the plurality of first adjustment plates 11 in the second direction N is 1/10 to 1/20 of a dimension of the first adjustment structure 1 in the second direction N; and a dimension of each of the plurality of second adjustment plates 21 in the second directions N is 1/10 to 1/20 of a dimension of the second adjustment structure 2 in the second direction N. That is, the first adjustment structure 1 is divided into 10 to 20 first adjustment plates 11 in the second direction N, and the second adjustment structure 2 is divided into 10 to 20 second adjustment plates 21 in the second direction N. In some embodiments, each of the plurality of first adjustment plates 11 and the corresponding one of the plurality of second adjustment plates 21 are equal in size in the second direction N, which facilitates a fine adjustment of the evaporation range.

It should be noted that the more the first adjustment plates 11 and the second adjustment plates 21 formed by dividing the first adjustment structure 1 and the second adjustment structure 2 in the second direction N, respectively, the more precise the adjustment of the evaporation range of the evaporation sources 3, Which is limited between the first adjustment structure 1 and the second adjustment structure 2, and the more uniform the thickness of the film layer formed by evaporation.

In some embodiments, adjacent ones of the plurality of first adjustment plates 11 are substantially seamlessly connected; and adjacent ones of the plurality of second adjustment plates 21 are substantially seamlessly connected. For example, adjacent ones of the plurality of first adjustment plates 11 are in direct contact (e.g., without any intermediate structures or components) without spacing therebetween, and adjacent ones of the plurality of second adjustment plates 21 are in direct contact (e.g., without any intermediate structures or components) without spacing therebetween. With this arrangement, it is possible to prevent a gap from being formed between the adjacent ones of the plurality of first adjustment plates 11 or between the adjacent ones of the plurality of second adjustment plates 21 during their movements, thereby preventing the evaporation material from being evaporated onto the substrate through the gap.

It should be noted that the seamless connections between the adjacent ones of the plurality of first adjustment plates 11 and between the adjacent ones of the plurality of second adjustment plates 21 can be realized in various manners, for example, adjacent ones of the plurality of first adjustment plates 11 or adjacent ones of the plurality of second adjustment plates 21 overlap with each other at their connected edge regions (i.e., adjacent adjustment plates have an overlapping portion in a direction perpendicular to the paper surface), and the overlapping portions can block the gap therebetween. Alternatively, the mutually connected side edges of the adjacent ones of the plurality of first adjustment plates 11 or the adjacent ones of the plurality of second adjustment plates 21 are closely fitted and slidable relatively to each other, that is, no gap is formed at the position where the adjacent ones are connected, so as to prevent the evaporation material from passing through the gap. Any way for implementing seamless connection between two adjacent adjustment plates is within the scope of the present disclosure.

Based on the above structure of the limitation structure, the present disclosure further provides an adjustment method of the limitation structure, including: moving the first adjustment structure and the second adjustment structure relative to each other to adjust a range of the spacing region formed between the first adjustment structure and the second adjustment structure.

In the adjustment method, by adjusting the range of the spacing region, the evaporation range of the evaporation sources can be adjusted so that a film having a uniform thickness can be formed by the evaporation sources through evaporation.

In some embodiments, the first adjustment structure and the second adjustment structure are arranged in a first direction perpendicular to the second direction; the first adjustment structure includes a plurality of first adjustment plates sequentially arranged in the second direction, the second adjustment structure includes a plurality of second adjustment plates sequentially arranged in the second direction, the plurality of first adjustment plates correspond to the plurality of second adjustment plates in the first direction; and a substrate to be coated is moved in the first direction for evaporation of the material onto the substrate to be coated. The step of moving the first adjustment structure and the second adjustment structure relative to each other includes: moving each of the plurality of first adjustment plates of the first adjustment structure and a corresponding one of the plurality of second adjustment plates of the second adjustment structure in the first direction to adjust a spacing in the first direction between the first adjustment plate and the corresponding one of the plurality of second adjustment plates.

By providing the first adjustment structure and the second adjustment structure configured to be movable relative to each other, the above-described limitation structure provided by the embodiments of the present disclosure can adjust the range of the spacing region formed between the first adjustment structure and the second adjustment structure, thereby the evaporation range for the evaporation sources can be adjusted. Compared with the existing limitation plate structure by which the evaporation range limited cannot be adjusted, the limitation structure in the present embodiments can adjust the evaporation range, so that the thickness of the film layer formed by evaporation is more uniform, thereby improving the performance of the product formed by the evaporation and enhancing the competitiveness of the product.

In another aspect, the present disclosure also provides a limitation device. FIG. 4 is a plan view of a structure of a limitation device in accordance with some embodiments of the present disclosure. As shown in FIG. 4, in some embodiments, the limitation device includes the limitation structure in the above embodiments, for example, the limitation structure shown in FIG. 3.

In some embodiments, the limitation device further includes a first control part 4 coupled to the first adjustment plate 11 of the limitation structure and configured to control movement of the first adjustment plate 11, and a second control part 5 coupled to the second adjustment plate 21 of the limitation structure and configured to control the movement of the second adjustment plate 21.

In some embodiments, one or more first control parts 4 may be provided. In some embodiments, a plurality of first control parts 4 are provided, and the plurality of first control parts 4 are coupled to the plurality of first adjustment plates 11 in one-to-one correspondence. In some embodiments, one or more second control parts 5 may also be provided. In some embodiments, a plurality of second control parts 5 are provided, and the plurality of second control parts 5 are coupled to the plurality of second adjustment plates 21 in one-to-one correspondence. In some embodiments, the first control part 4 and the second control part 5 may each take the form of a motor.

In some embodiments, the limitation device further includes a calculating part 8 coupled to the first control part 4 and the second control part 5 and configured to calculate a spacing in the first direction M between each of the plurality of first adjustment plates 11 and a corresponding one of the plurality of second adjustment plates 21. The first control part 4 and the second control part 5 are configured to respectively control the first adjustment plate 11 and the second adjustment plate 21 to move in the first direction M based on the calculated spacing. In some embodiments, the calculating part 8 may be a computer, a microprocessor, a dedicated processing circuit, a microcontroller, or the like. It should be understood here that a simplified illustration of the coupling of the calculating part 8 with one first control part 4 and one second control part 5 is shown by way of example only in FIG. 4, the calculating part 8 is actually coupled with all of the first control parts 4 and all of the second control parts 5 to control them.

For example, the calculating part 8 calculates the spacing in the first direction M between each of the first adjustment plates 11 and a corresponding one of the second adjustment plates 21 in accordance with the evaporation process conditions. For example, the operation of the calculating part 8 is: fitting a distribution curve function of a thickness (which is not uniform in this case) of a film formed on the substrate to be coated by evaporating a material using conventional limitation plates having a standard shape (that is, the evaporation range limited by two limitation plates is the same for each position, e.g., the limitation plates shown in FIG. 2); then, the motor is controlled to change a spacing between each of the first adjustment plates 11 and a corresponding one of the second adjustment plates 21 in the first direction M. The change of the spacing follows the above fitted distribution curve, so that the evaporation range of the evaporation sources 3 is changed to finally make the thickness of the film layer formed by evaporation more uniform.

The following is an example of the operation of the calculating unit 8. For example, for a line source (i.e., a line evaporation source for evaporating a material) consisting of n point evaporation sources, a point evaporation source 1, a point evaporation source 2, . . . , and a point evaporation source n may individually form films having thickness distributions represented by f₁ (x, y), f₂ (x, y), . . . , and fₙ (x, y), respectively, in a two-dimensional plane defined by the first direction as the horizontal axis x and the second direction as the vertical axis y, and the overlapped thickness distribution of the films formed by these point evaporation sources in the two-dimensional plane may be represented by a function Y(x, y), where Y(x, y)=f₁ (x, y)+f₂ (x, y)+ . . . +fₙ (x, y).

It is assumed that during the evaporation process, the substrate to be coated is moved in the x-axis direction to form a material film layer on the entire substrate to be coated by evaporation. Here, assuming that two limitation plates having a standard shape (i.e., the evaporation range limited between the two limitation plates is equal at every position along the y-axis direction, for example, the limitation plates shown in FIG. 2) have a distance L therebetween in the x-axis direction and the adjustable range of each of the first adjustment plate and the second adjustment plate is L/2 in the x-axis direction, the overlapped thickness distribution function Y(x, y) is integrated in the x-axis direction to obtain:

$$Y ( y ) = {\int }_{0}^{L / 2} Y ( x , y ) d x$$

Y(y) refers to a thickness, in the y-axis direction where the line source is arranged, of the film (in a line along the x-axis direction corresponding to each point evaporation source) formed by evaporation on the substrate to be coated within an evaporation range limited by two limitation plates. Here, when two limitation plates having a standard shape have been employed, the thickness Y(y) of the film formed by evaporation is different at different position y on the y-axis, that is, the thickness of the film is not uniform.

In the case where the evaporation rate is stable, assuming that the target thickness of the uniform film to be achieved is H, then the following should be satisfied:

Y(y)*x′=H

where x′ represents a distance between the first adjustment plate and the second adjustment plate in the x-axis direction at a certain position in the y-axis direction. Since Y(y) is different at different positions in the y-axis direction, the distance between the first adjustment plate and the second adjustment plate in the x-axis direction changes as the value of y in the y-axis direction changes. In this way, a set of x′ values is obtained. Under the control of the calculating part, the motor drives the first adjustment plate and the second adjustment plate correspondingly disposed along the x-axis direction to move, so that the thickness of film formed on the substrate to be coated by evaporation becomes more uniform.

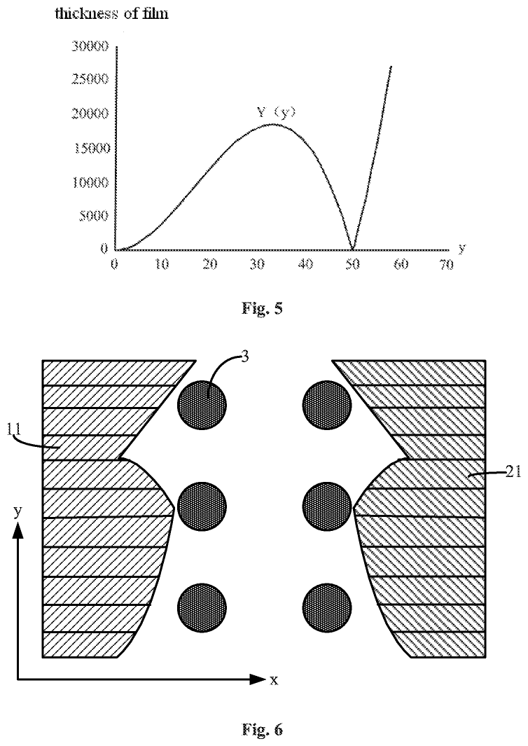

For example, assuming that there are six evaporation sources 3 and the curve of function Y(y) fitted by the calculating part is represented by Y(y)=100+y³−50y²−y, as shown in FIG. 5. Then, the motor, which is under the driving of the calculating part, drives each of the first adjustment plate 11 and each of the second adjustment plate 21 to move to set positions, and the shape formed by the first adjustment plates 11 and the second adjustment plates 21 after the movements is as shown in FIG. 6. In this way, it is possible to make the thickness of the film formed on the substrate to be coated by evaporation more uniform.

Based on the above structure of the limitation device, the present disclosure also provides an adjustment method of the limitation device, including the adjustment method of the limitation structure described above. The adjustment method of the limitation device further includes: calculating, by the calculating part, a spacing between each of the first adjustment plates and a corresponding one of the second adjustment plates in the first direction; and controlling, by the first control part and the second control part, each of the first adjustment plates and the corresponding one of the second adjustment plates to move in the first direction based on the calculated spacing.

By employing the limitation structure provided in the above embodiments, the limitation device provided by the present disclosure can adjust the range of the spacing region formed between the first adjustment structure and the second adjustment structure to adjust the evaporation range of the evaporation sources, so that the thickness of the film layer formed by evaporation is more uniform, thereby improving the performance of the product formed by the evaporation and enhancing the competitiveness of the product.

The present disclosure further provides an evaporation system, including the limitation device described herein.

By employing the limitation device described herein, the evaporation system can form a film layer having a more uniform thickness, thereby improving the performance of the product formed by evaporation and enhancing the competitiveness of the product.

It is to be understood that the above embodiments are merely exemplary embodiments for the purpose to explain the principles of the present disclosure, but the present disclosure is not limited thereto. Various modifications and improvements can be made by those skilled in the art without departing from the spirit and scope of the present disclosure. These modifications and improvements are also considered to be within the protection scope of the present disclosure.

1. A limitation device for evaporation, comprising a limitation structure, the limitation structure comprising a first adjustment structure and a second adjustment structure disposed on a same plane, a side of the first adjustment structure being opposite to a side of the second adjustment structure, and the first adjustment structure and the second adjustment structure being spaced apart from each other to form a spacing region, wherein the first adjustment structure and the second adjustment structure are movable relative to each other to adjust a range of the spacing region.

2. The limitation device of claim 1, wherein the first adjustment structure and the second adjustment structure are arranged in a first direction perpendicular to a second direction;
the first adjustment structure comprises a plurality of first adjustment plates sequentially arranged in the second direction, and the second adjustment structure comprises a plurality of second adjustment plates sequentially arranged in the second direction;
the plurality of first adjustment plates correspond to the plurality of second adjustment plates in the first direction, and each of the plurality of first adjustment plates and each of the plurality of second adjustment plates are both movable in the first direction to adjust a spacing in the first direction between each of the plurality of first adjustment plates and a corresponding one of the plurality of second adjustment plates.

3. The limitation device of claim 2, wherein the plurality of first adjustment plates and the plurality of second adjustment plates are in one-to-one correspondence in the first direction.

4. The limitation device of claim 3, wherein a number of the plurality of first adjustment plates is the same as a number of the plurality of second adjustment plates, and a central axis of each of the plurality of first adjustment plates in the first direction and a central axis of the corresponding one of the plurality of second adjustment plates in the first direction mutually coincide.

5. The limitation device of claim 2, wherein a dimension of each of the plurality of first adjustment plates in the second direction is 1/10 to 1/20 of a dimension of the first adjustment structure in the second direction; and
a dimension of each of the plurality of second adjustment plates in the second directions is 1/10 to 1/20 of a dimension of the second adjustment structure in the second direction.

6. The limitation device of claim 2, wherein adjacent first adjustment plates of the plurality of first adjustment plates are substantially seamlessly connected; and adjacent second adjustment plates of the plurality of second adjustment plates are substantially seamlessly connected.

7. The limitation device of claim 2, wherein adjacent first adjustment plates of the plurality of first adjustment plates are overlapped with each other at their connected edge regions; and adjacent second adjustment plates of the plurality of second adjustment plates are overlapped with each other at their connected edge regions.

8. The limitation device of claim 2, wherein mutually connected side edges of adjacent first adjustment plates of the plurality of first adjustment plates are fitted; and mutually connected side edges of adjacent second adjustment plates of the plurality of second adjustment plates are fitted.

9. The limitation device of claim 2, further comprising a first control part and a second control part; wherein
the first control part is coupled to a first adjustment plate of the limitation structure and configured to control movement of the first adjustment plate; and
the second control part is coupled to a second adjustment plate of the limitation structure and configured to control movement of the second adjustment plate.

10. The limitation device of claim 9, further comprising a calculating part coupled to the first control part and the second control part and configured to calculate a spacing in the first direction between the first adjustment plate and the second adjustment plate corresponding to each other; and
the first control part and the second control part are configured to control the first adjustment plate and the second adjustment plate to move in the first direction based on the calculated spacing, respectively.

11. The limitation device of claim 1, wherein the spacing region is configured to allow an evaporation material evaporated from an evaporation source at a side of the limitation device to pass through the spacing region to be deposited on a substrate at an opposite side of the limitation device, and
wherein the limitation device is configured to adjust an evaporation range of the evaporation source by adjusting the spacing region.

12. An evaporation system, comprising the limitation device of claim 1.

13. An adjustment method of a limitation structure, the limitation structure comprising a first adjustment structure and a second adjustment structure disposed on a same plane, a side of the first adjustment structure being opposite to a side of the second adjustment structure, and the first adjustment structure and the second adjustment structure being spaced apart from each other to form a spacing region, the first adjustment structure and the second adjustment structure being movable relative to each other, and the method comprising a step of: moving the first adjustment structure and the second adjustment structure relative to each other to adjust a range of the spacing region formed between the first adjustment structure and the second adjustment structure.

14. The adjustment method of claim 13, wherein the first adjustment structure and the second adjustment structure are arranged in a first direction perpendicular to a second direction; the first adjustment structure comprises a plurality of first adjustment plates sequentially arranged in the second direction, and the second adjustment structure comprises a plurality of second adjustment plates sequentially arranged in the second direction; the plurality of first adjustment plates correspond to the plurality of second adjustment plates in the first direction; a substrate to be coated is configured to be moved in the first direction to achieve evaporation of a material on the substrate to be coated, and wherein
the step of moving the first adjustment structure and the second adjustment structure relative to each other comprises: moving each of the plurality of first adjustment plates of the first adjustment structure and a corresponding one of the plurality of second adjustment plates of the second adjustment structure in the first direction, thereby adjusting a spacing in the first direction between each of the plurality of first adjustment plates and the corresponding one of the plurality of second adjustment plates.

15. An adjustment method of a limitation device, the limitation device comprising a limitation structure comprising a first adjustment structure and a second adjustment structure disposed on a same plane, a side of the first adjustment structure being opposite to a side of the second adjustment structure, and the first adjustment structure and the second adjustment structure being spaced apart from each other to form a spacing region, the first adjustment structure and the second adjustment structure being movable relative to each other, and the method comprising a step of:
moving the first adjustment structure and the second adjustment structure relative to each other to adjust a range of the spacing region formed between the first adjustment structure and the second adjustment structure.

16. The adjustment method of claim 15, wherein the first adjustment structure and the second adjustment structure are arranged in a first direction perpendicular to a second direction; the first adjustment structure comprises a plurality of first adjustment plates sequentially arranged in the second direction, and the second adjustment structure comprises a plurality of second adjustment plates sequentially arranged in the second direction; and the plurality of first adjustment plates correspond to the plurality of second adjustment plates in the first direction;
the limitation device further comprises a first control part coupled to a first adjustment plate of the limitation structure and a second control part coupled to a second adjustment plate of the limitation structure; and wherein
the method further comprises: moving, by the first control part and the second control part respectively, the first adjustment plate of the first adjustment structure and the second adjustment plate of the second adjustment structure in the first direction to adjust a spacing in the first direction between the first adjustment plate and the second adjustment plate corresponding to each other.

17. The adjustment method of claim 16, wherein the limitation device further comprises a calculating part coupled to the first control part and the second control part, and the method further comprises:
calculating, by the calculating part, the spacing in the first direction between the first adjustment plate and the second adjustment plate corresponding to each other; and
controlling, by the first control part and the second control part respectively, the first adjustment plate and the second adjustment plate corresponding to each other to move in the first direction based on the calculated spacing.

18. The evaporation system of claim 12, wherein the first adjustment structure and the second adjustment structure are arranged in a first direction perpendicular to a second direction;
the first adjustment structure comprises a plurality of first adjustment plates sequentially arranged in the second direction, and the second adjustment structure comprises a plurality of second adjustment plates sequentially arranged in the second direction;
the plurality of first adjustment plates correspond to the plurality of second adjustment plates in the first direction, and each of the plurality of first adjustment plates and each of the plurality of second adjustment plates are both movable in the first direction to adjust a spacing in the first direction between each of the plurality of first adjustment plates and a corresponding one of the plurality of second adjustment plates.

19. The evaporation system of claim 18, wherein the plurality of first adjustment plates and the plurality of second adjustment plates are in one-to-one correspondence in the first direction.

20. The evaporation system of claim 19, wherein a number of the plurality of first adjustment plates is the same as a number of the plurality of second adjustment plates, and a central axis of each of the plurality of first adjustment plates in the first direction and a central axis of the corresponding one of the plurality of second adjustment plates in the first direction mutually coincide.
